(19) United States
(12) Patent Application Publication
(10) Pub. No.: US 2024/0126934 A1
(43) Pub. Date: Apr. 18, 2024

(54) VIRTUAL PERFORMANCE COMPATIBILITY CHECKING AND MANAGEMENT FOR MODULAR CONSTRUCTION AND RELATED METHODS

(71) Applicant: North Carolina State University, Raleigh, NC (US)

(72) Inventors: Kook In Han, Raleigh, NC (US); Abhinav GUPTA, Raleigh, NC (US); Seyedmojtaba NOGHABAEI, Raleigh, NC (US)

(21) Appl. No.: 18/280,425

(22) PCT Filed: Mar. 5, 2022
(86) PCT No.: PCT/US2022/070993

§ 371 Date: Sep. 5, 2023

Related U.S. Application Data
(60) Provisional application No. 63/157,119, filed on Mar. 5, 2021.

(51) Int. Cl. G06F 30/12; G06F 30/13

(52) U.S. Cl. CPC G06F 30/12; G06F 30/13

(57) ABSTRACT

Various examples are provided related to virtual performance compatibility checking and management for modular construction. In one example, a method includes segmenting boundaries of as-built and as-planned models of a construction element; determining features of each boundary segment of the as-built and as-planned models; determining similarity ratios for matching pairs of boundary segments of the as-built and as-planned models; comparing a total similarity ratio based upon the similarity ratios for matching pairs of boundary segments with a specified threshold; and snapping the as-built model in position in a point cloud in response to the comparison. A system comprising computing or processing circuitry can execute a program or application to implement the similarity/compatibility checking methodology. The similarity/compatibility checking methodology can be implemented within a construction performance modeling and simulation (CPMS) framework.

### CROSS REFERENCE TO RELATED APPLICATIONS

This application claims priority to, and the benefit of, co-pending U.S. provisional application entitled “Virtual Performance Compatibility Checking and Management for Modular Construction and Related Methods” having Ser. No. 63/157,119, filed Mar. 5, 2021, which is hereby incorporated by reference in its entirety.

### STATEMENT REGARDING FEDERALLY SPONSORED RESEARCH OR DEVELOPMENT

The present invention was made with United States government support under grant number DE-AR0001155 awarded by the U.S. Department of Energy Advanced Research Projects Agency. The United States government has certain rights in the invention.

### BACKGROUND

Architecture, engineering, and construction (AEC) industry is among the largest industries in the United States with spending reaching over $1.3 trillion in 2019. However, over 98% of large-scale construction projects incur cost overruns and delays. Many projects experience rework, which can cost from 5% to 20% of the total contract value. The main causes of rework include lack of communication among different construction parties, lack of adequate visualization capability to recognize design conflicts, lack of support for advanced communication technologies, and lastly, incompatibility of as-built modules. These high escalations in overnight construction costs and schedule delays related to rework have made many projects commercially unattractive.

### SUMMARY

Aspects of the present disclosure are related to virtual performance compatibility checking and management for modular construction and related methods. The presented framework can model and simulate construction performance in a virtual environment, denoted hereafter as Construction Performance Modeling and Simulation (CPMS). CPMS can serve as a monitoring and digital data management solution that can serve stakeholders (e.g., contractor, vendor, designer, and owner) of a construction project. For example, CPMS can visualize as-build and as-planned models of a building under construction. It can also visualize modular components (fabricated at off-site facilities) along with the as-built/as-planned models of the building. The visualization can be automatically accomplished using a common global unique identifier (GUI D). The visualization can be independent of the compatibility check and can serve as an additional manual check by a user.

In one aspect, among others, a method for compatibility checking of modular construction comprises segmenting boundaries of as-built and as-planned models of a construction element; determining features of each boundary segment of the as-built and as-planned models; determining similarity ratios for matching pairs of boundary segments of the as-built and as-planned models; comparing a total similarity ratio based upon the similarity ratios for matching pairs of boundary segments with a specified threshold; and snapping the as-built model in position in a point cloud in response to the comparison. In one or more aspects, the determined features of each boundary segment of the as-built and as-planned models can comprise segment surface, segment dimension, and segment aggregated normal. The similarity ratios for matching pairs of boundary segments can be based upon the segment surface, segment dimension, and segment aggregated normal of the matching pair of boundary segments of the as-built and as-planned models.

In various aspects, determining features of each boundary segment can comprise determining highest and lowest points in a plurality of defined directions for each boundary segment. The as-built model can be snapped in position when the total similarity ratio is less than or equal to the specified threshold. Registration of the as-built model in the point cloud can be adjusted in response to the total similarity ratio exceeding the specified threshold. The as-built and as-planned models can be identified by a common global unique identifier (GUI D) and can be aligned with the as-built and as planned models of other building components. In some aspects, the construction element can be configured to couple to a second construction element along a coupling interface. The method can comprise comparing the as-built model of the construction element to an as-built model of the second construction element along the coupling interface. The comparison can comprise comparing features of boundary segments along the coupling interface of the as-built model of the construction element to features of corresponding boundary segments along the coupling interface of the as-built model of the second construction element. The features of each boundary segment can comprise highest and lowest points in a plurality of defined directions for each boundary segment. The as-built models of the construction elements can be displayed in a user interface in a coupled orientation. The compatibility checking method can be implemented within a construction performance modeling and simulation (CPMS) framework.

In another aspect, a system comprises processing circuitry comprising a processor and memory; and a similarity and compatibility checking program (or application) executable by the processing circuitry. Execution of the similarity and compatibility checking program can cause the processing circuitry to: segment boundaries of as-built and as-planned models of a construction element; determine features of each boundary segment of the as-built and as-planned models; determine similarity ratios for matching pairs of boundary segments of the as-built and as-planned models; compare a total similarity ratio based upon the similarity ratios for matching pairs of boundary segments with a specified threshold; and snap the as-built model in position in a point cloud in response to the comparison.

In one or more aspects, the determined features of each boundary segment of the as-built and as-planned models can comprise segment surface, segment dimension, and segment aggregated normal. The similarity ratios for matching pairs of boundary segments can be based upon the segment surface, segment dimension, and segment aggregated normal of the matching pair of boundary segments of the as-built and as-planned models. The as-built model can be snapped in position when the total similarity ratio is less than or equal to the specified threshold. Registration of the as-built model in the point cloud can be adjusted in response to the total similarity ratio exceeding the specified threshold. In various aspects, execution of the similarity and compatibility checking program can cause the processing circuitry to compare the as-built model of the construction element to an as-built model of a second construction element along a coupling interface. The comparison can comprise comparing features of boundary segments along the coupling interface of the as-built model of the construction element to features of corresponding boundary segments along the coupling interface of the as-built model of the second construction element.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described embodiments are usable in all aspects of the disclosure taught herein. Furthermore, the individual features of the dependent claims, as well as all optional and preferred features and modifications of the described embodiments are combinable and interchangeable with one another.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 illustrates an example of CPMS in a supply chain loop, in accordance with various embodiments of the present disclosure.

FIG. 2 illustrates examples of generated point clouds of a construction site, in accordance with various embodiments of the present disclosure.

FIG. 3 is a flow chart illustrating an example of the compatibility checking and management framework, in accordance with various embodiments of the present disclosure.

FIGS. 4A and 4B illustrate an example of registration of BIM and point cloud using cloud compare software, in accordance with various embodiments of the present disclosure.

FIG. 5 illustrates an example of an interface displaying aligned point cloud and imaging, in accordance with various embodiments of the present disclosure.

FIGS. 6A-6E illustrate examples of an interface displaying a compatibility check mode, in accordance with various embodiments of the present disclosure.

FIG. 7 is a flow chart illustrating an example of a similarity check function, in accordance with various embodiments of the present disclosure.

FIGS. 8A-8C illustrate an example of segmentation and similarity processes, in accordance with various embodiments of the present disclosure.

FIG. 9 illustrates an example of as-built and as-planned model comparison, in accordance with various embodiments of the present disclosure.

FIGS. 10A and 10B and FIGS. 11A-110 illustrate examples of as-built model comparisons of coupled elements, in accordance with various embodiments of the present disclosure.

FIG. 12 is a schematic block diagram illustrating an example of a system employed for similarity and compatibility checking and management, in accordance with various embodiments of the present disclosure.

### DETAILED DESCRIPTION

Disclosed herein are various examples related to virtual performance compatibility checking and management for modular construction and related methods. Reference will now be made in detail to the description of the embodiments as illustrated in the drawings, wherein like reference numbers indicate like parts throughout the several views.

Inefficiencies resulting from escalations in overnight construction costs and schedule delays may be resolved through an integrated framework that visualizes the state of the construction along with BIM at the same time. Much of the research and development has focused on developing new reactor designs with accident tolerant fuels and passive safety systems intended to reduce operating and lifecycle costs. This disclosure presents a monitoring framework for modular construction that uses a virtual environment to digitally manage Quality Control (QC) inspections and construction progress and improve supply chain efficiency. This framework can help the construction industry lower fabrication and construction costs, contributing to reducing the overnight construction costs.

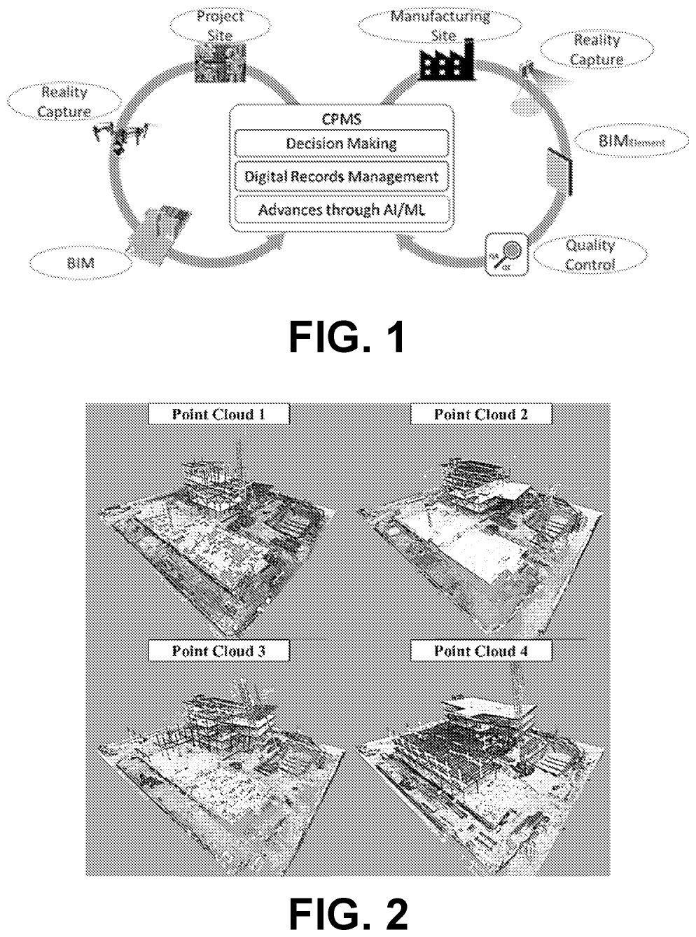

This innovative concept builds upon advances in building information modeling (BIM) and reality capture that utilize the power of 3D laser scanners and camera-equipped drones for 3D image/video processing. The presented framework can model and simulate construction performance in a virtual environment, denoted hereafter as Construction Performance Modeling and Simulation (CPMS). CPMS can facilitate decision making through a virtually connected construction site and off-site facilities. The presented solution can be embedded into the supply chain loop to ensure ongoing quality control, simulation of weekly progress and work schedules, and timely decision support throughout the construction process. FIG. 1 schematically illustrates an example of CPMS in the supply chain loop. Additional details can be found in “Performance monitoring of modular construction through a vertically connected project site and off-site manufacturing facilities” by K. Han and A. Gupta (Transactions, SMiRT-25, August 2019), which is hereby incorporated by reference in its entirety.

As-built modeling using 3D reconstruction. Data collection is a first step in point cloud (as-built model) generation. For example, a drone can be flown around an existing site (e.g., a construction site) to obtain images of the project at short time intervals to facilitate collection of the data. This allows images of as much of the project as possible to be captured in a flowing pattern around the site. Taking pictures using this method can increase the probability of creating a dense point cloud with as few holes as possible. In addition, CPMS can also visualize other types of 3D models, such as 3D laser scans that can primarily be used for quality assessment of offsite and/or prefabricated components.

Once the captured images (or scans) have been recorded, a 3D reality capture software (e.g., Pix4D in the presented examples but any other appropriate image processing software can be used) can generate a 3D point cloud from the 2D images. FIG. 2 shows examples of point clouds of a construction site generated using the Pix4D software. In the reconstruction process, the camera's intrinsic and extrinsic properties for each image can be determined and logged to an output file. This file can later be parsed to determine each camera's position and viewing direction. This information in the output file can then be transformed into a readable format for a 3D engine.

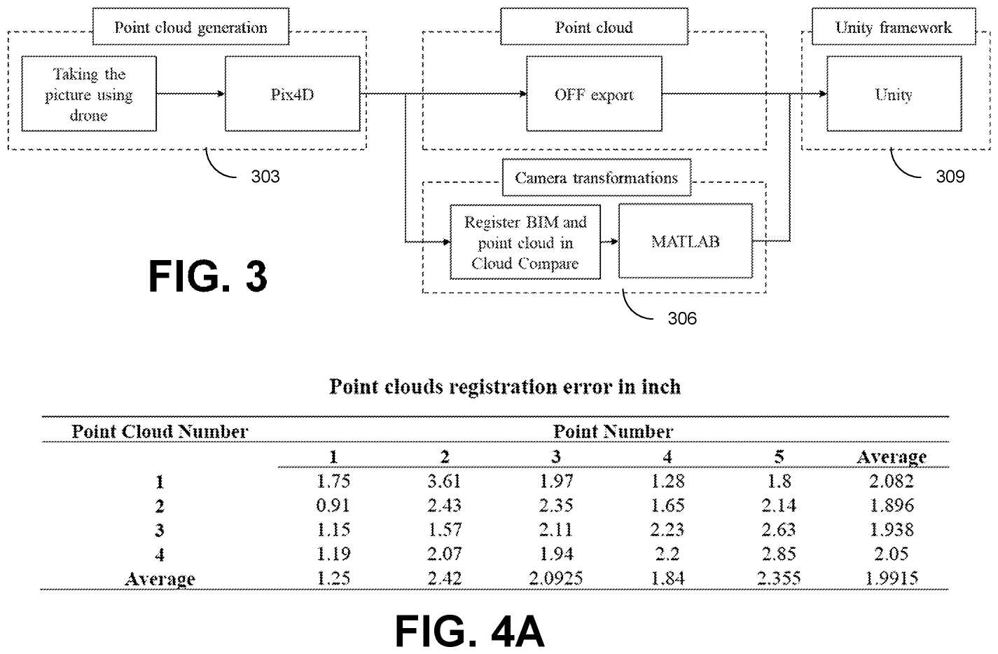

FIG. 3 is a flow chart illustrating an example of the compatibility checking and management framework methodology. This framework includes three main sections: point cloud generation 303, camera transformation 306, and Unity framework 309 (a 3D game engine but any 3D visualization tools/libraries can be used). The first section 303 comprises generation of the point cloud from the acquired images using image processing software (Pix4D). The point cloud can be generated by finding corresponding features from the recorded images of the site. The second section 306 comprises camera transformations, where the details of how transformation matrixes from the point cloud generation section 303 are interpreted and converted in a format that is readable for 3D engines (e.g., using Matlab software). Prior to this, the BIM and point cloud can be imported into a cloud compare software for accurate manual registration of the BIM and point cloud information. The registration operation generates a transformation and rotation matrix for point cloud, which can later be imported in the Unity engine or Three.JS for the web version (Three.JS is an open source library based on WebGL that is used in addition to Unity to develop a lighter version of the framework for web applications). The Unity framework section illustrates how the framework works and introduces the framework functionalities.

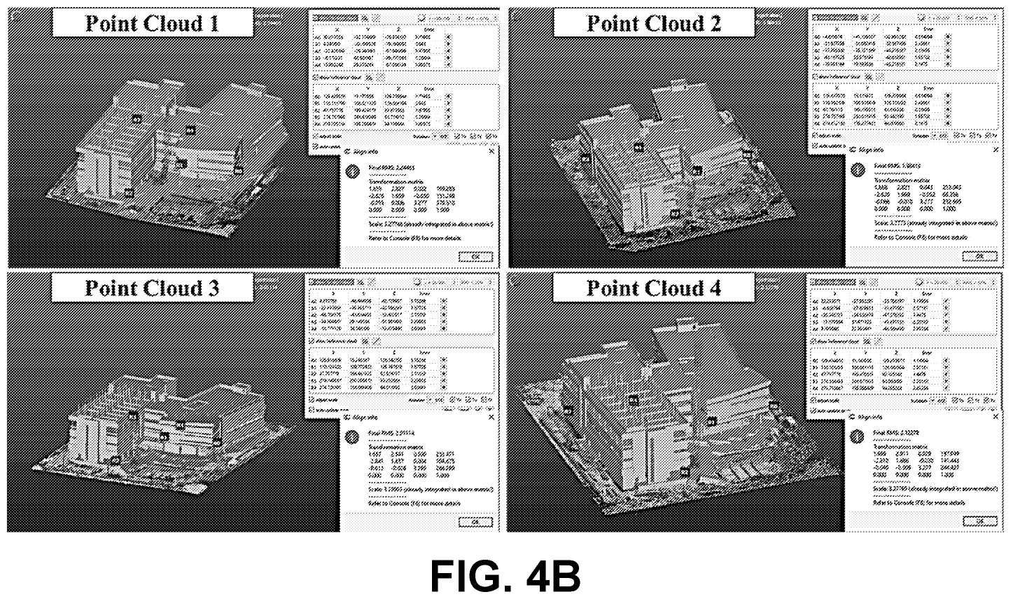

Point cloud registration. FIGS. 4A and 4B illustrate an example of the process of manual registration of BIM and point cloud utilizing cloud compare software. Five points were selected from the BIM and point cloud to perform the registration. By selecting the points, cloud compare software can automatically generate a transformation and rotation matrix, which will be later used in Unity or Three.JS. Also, the cloud compared software can show the error associated with each point, showing how accurate the registration process was performed. The registration accuracy is between 1 to 6 inches on average. The table of FIG. 4A shows the accuracy of each point in each point cloud and the average accuracy in inches and FIG. 4B illustrates the point could registration accuracies. The average accuracy was less than 2 inches.

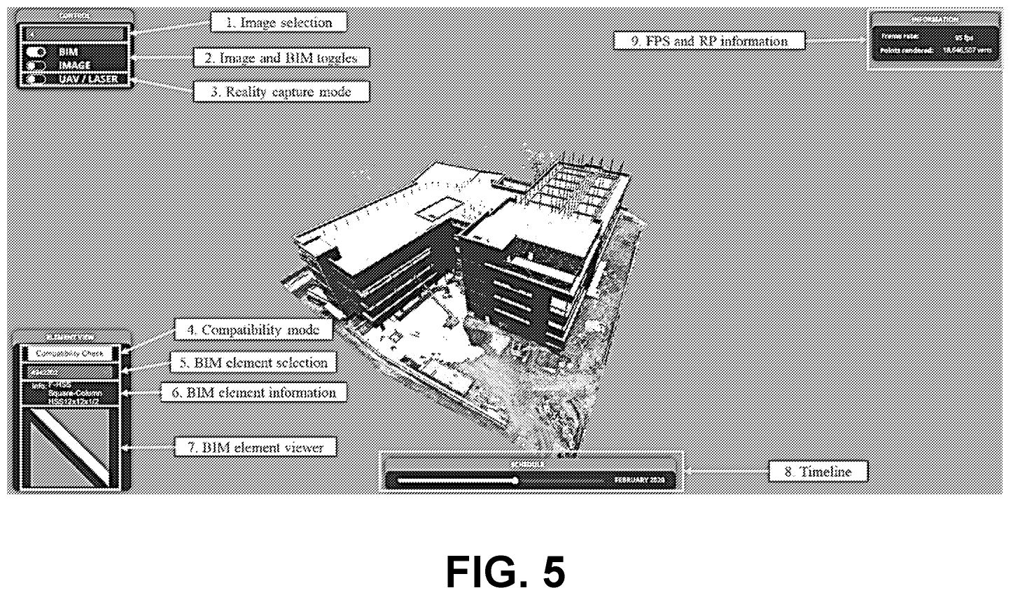

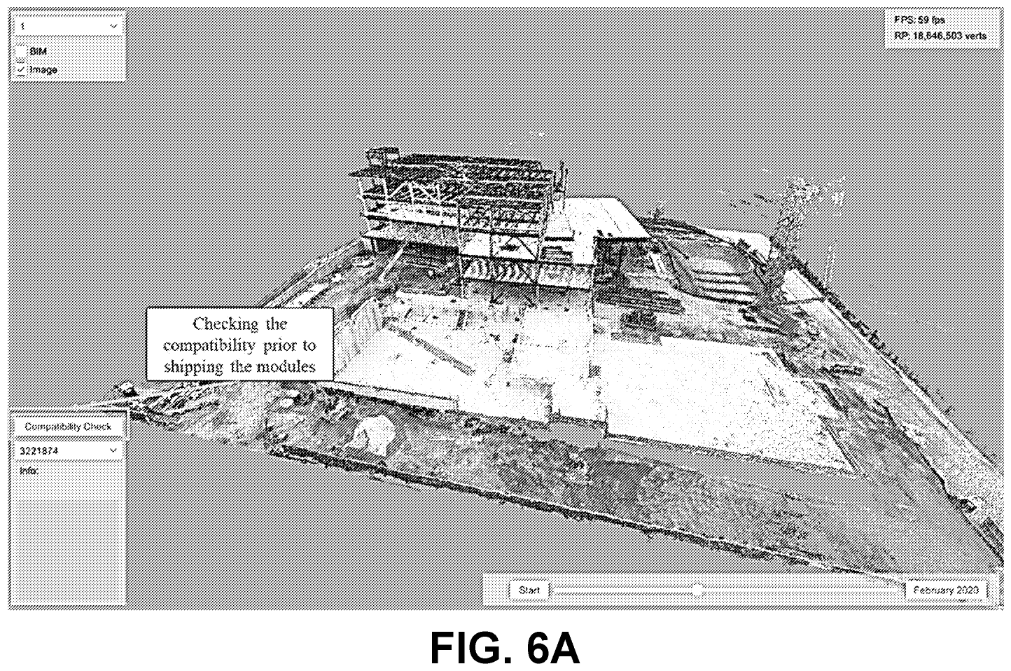

Framework details. As the camera parameters can be stored in a CSV file, Unity C #scripts can be written to plot the images and to be able to move the field of view to each image. To plot the images, the CSV file can be read, and a game object can be instantiated with the position and “look at” direction of each camera determined. The look at vector can then be multiplied by the focal length of the camera and a scale factor. The image position can be found by adding this resultant vector to the camera's position, and another game object can be instantiated. The Unity project can contain a game object for each camera and image used for the reconstruction. To apply the image to the game object, a Unity material can be created for each of the images. In the plotter script, the corresponding material can then be applied to the image game object. For example, when an image number is selected from a dropdown menu (in the Unity framework 309 of FIG. 3), the Unity camera can be translated, and the look at direction can be transformed to the corresponding camera game object. This transformation can display the image aligned with the point cloud or mesh. FIG. 5 illustrates an example of the Unity interface displaying aligned point cloud. The Unity framework can include one or more of the following features:
A real image can be selected from section 1 of FIG. 5. The photos or images (which can be used in, e.g., VisualSFM) can be transferred and aligned with BIM and point clouds automatically using MATLAB and Unity scripts.
The BIM and image can be turned on and off for better visualization and improving the user experience in section 2 of FIG. 5.
The framework can switch between UAV point clouds and laser scanner point clouds in section 3 of FIG. 5.
The framework can switch to a compatibility mode, as will be discussed below, in section 4 of FIG. 5.
The framework can show each BIM element and the related information in sections 5,6, and 7 of FIG. 5.
A timeline can be presented and designed so the user can move a slider to the required time point in section 8 of FIG. 5. Each time point can render the corresponding point cloud and the BIM model. At each time point, elements of the BIM can be displayed using colors to show the schedule condition. For example, the BIM can be color-coded into four primary colors. Opaque white on BIM elements can indicate that the construction of the parts is completed. Transparent white can indicate that the element has not been constructed yet, and the construction time of that element has not been reached according to the schedule. Green can indicate that the element is under construction, and the construction is ahead of schedule, and red can indicate that the element is under construction, but the construction is behind schedule.
The number of rendered points (RP) in each frame and the number of frames rendered per second (FPS) can be shown in a separate window in section 9 of FIG. 5.

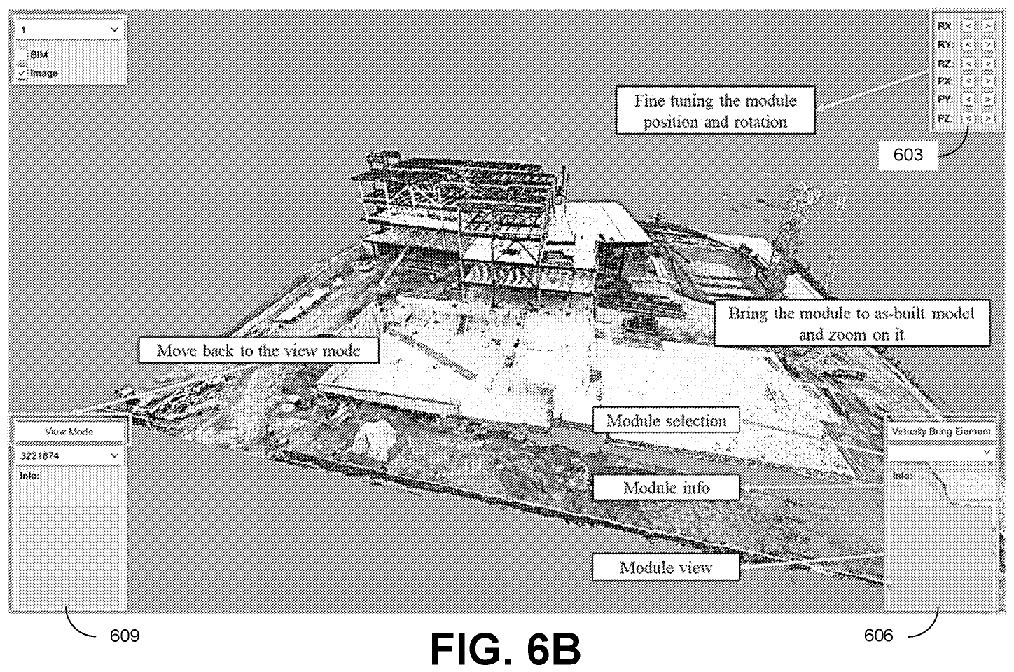

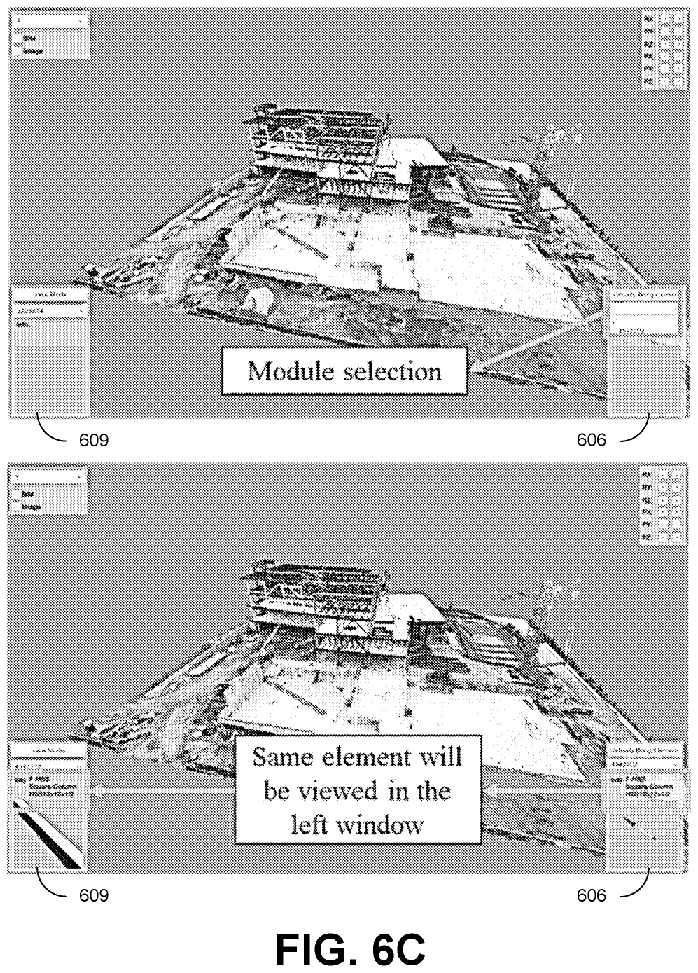

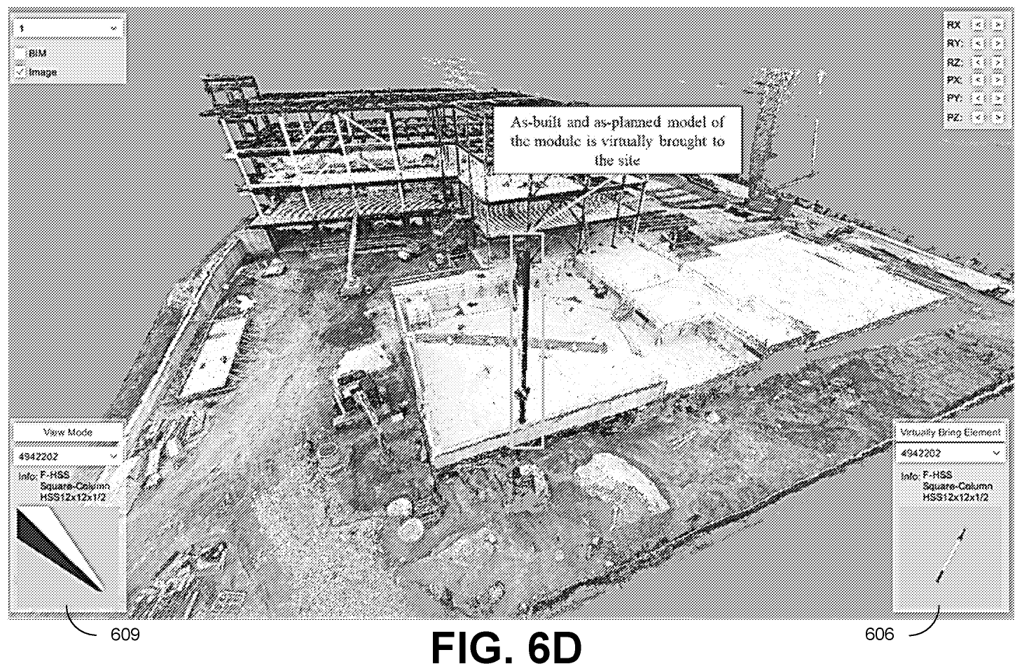

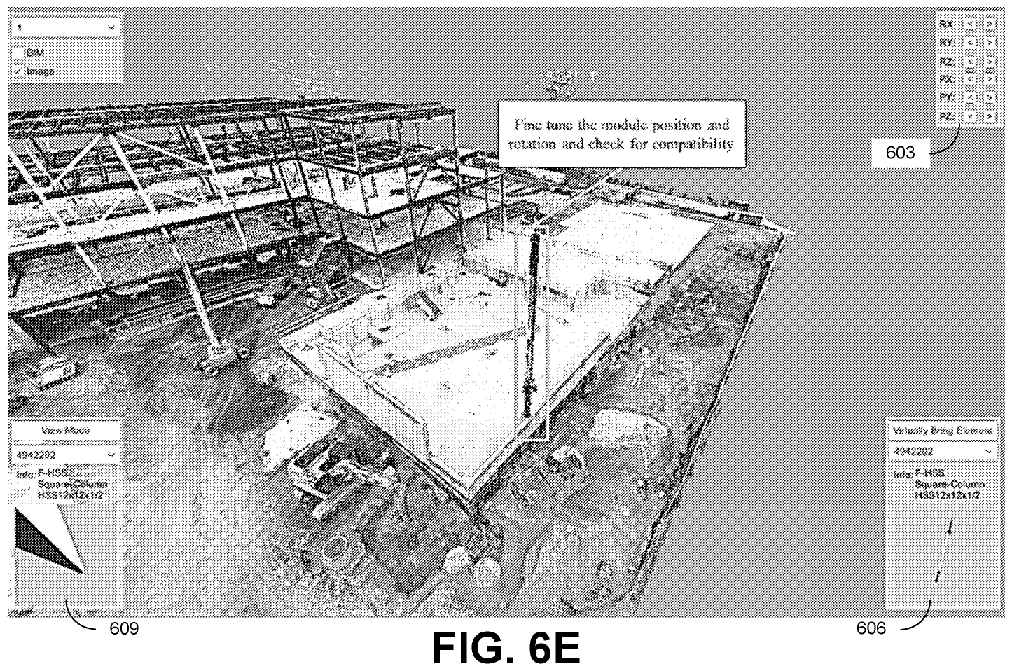

Compatibility check mode in CPMS framework. The compatibility check mode is a new feature of the framework. To enter the compatibility check mode, a button or other selection icon can be included. By selecting or “clicking” on this button or icon, the user can move to the compatibility check mode as illustrated in FIG. 6A, where the user can check the compatibility of manufactured modules in manufacturing plants with the as-built and as-planned models before shipping the actual modules to the site.

Inside the compatibility mode, the user can see three main components. The components are illustrated in FIG. 6B. The first component 603 (shown in the top right corner) can control the position and rotation of the manufactured module that is brought virtually to the as-built model for compatibility checks. The second component 606 (shown in the bottom right corner) can allow the user to select the remote module and the information of the remote module will be demonstrated according to the selection. The user can bring the selected element to the as-built model for performing compatibility checks by clicking on “virtually bring element.” A GUID (Global Unique ID) is used to associate prefabricated components with their CAD/BIM model. This allows automatic registration of as-built model of a prefabricated component with the rest of the structure. The third component (shown in the bottom left corner) can show the corresponding BIM element of the remote module that was selected previously in 609. The user can move out of compatibility mode by clicking on “view mode.”

FIG. 6C illustrates the procedure for selecting the remote module. By selecting a manufactured module in 606 (top image), the framework automatically finds the corresponding as-planned component with the same GUID and shows the BIM element in 609 as shown the bottom image of FIG. 6C. After the user selects the element and clicks on “virtually bring element”, the framework can automatically zoom to the position of the element in the model in FIGS. 6D and 6E. The framework brings the remote module and places it in the corresponding BIM element position as shown in FIG. 6D. This position is not necessarily accurate and depends on the process of laser scanning. The position and rotation of the element can then be modified (or fine-tuned) using the buttons (or icons) in 603 as shown in FIG. 6E. After fine-tuning the position and rotation of the remote module, the inspection process can be carried out in FIG. 6E. The user can move and virtually inspect the joints and compatibility of the scanned module with an as-built model and after approval, the remote module can be sent to the site.

Automated Compliance of as-Built Components

As-built to as-planned compatibility. To automate the process of compliance checking between as-built and as-planned versions of an element, a similarity check function can be implemented. This function can compute the similarity between the as-built model that is virtually brought (offsite element) and its as-design element and tell if the virtual element meets the specified standards set by the user as a threshold. This function can be used to manually fine-tune the offsite element position by allowing “snapping” of the element to its as-design position when the difference between the two positions fall below the user given threshold as described above with respect to FIGS. 6D and 6E.

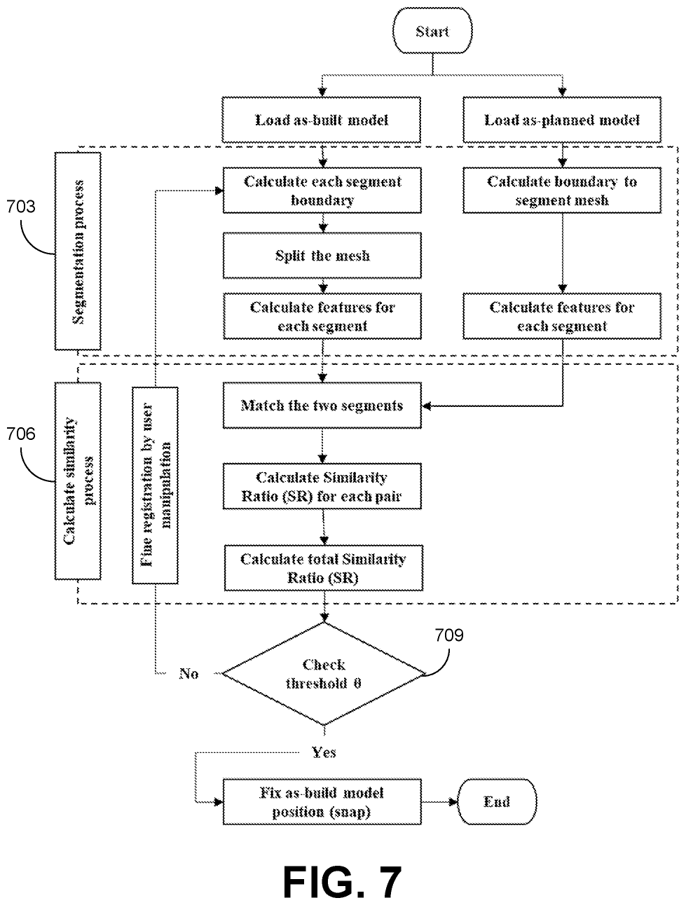

FIG. 7 is a flow chart illustrating an example of the methodology of a similarity check function. Initially, the as-built and as-planned models are loaded. Then, the as-built and as-planned models can be segmented by a segmentation process 703. This process can split the mesh into small segments (depending on a selected number of segments). The as-built model can then be compared to the as-planned model by a similarity process 706. If the specified standards are satisfied at 709, then the as-built model can be fixed in position. If not, then fine tuning of the as-built model can be carried out and compatibility check repeated.

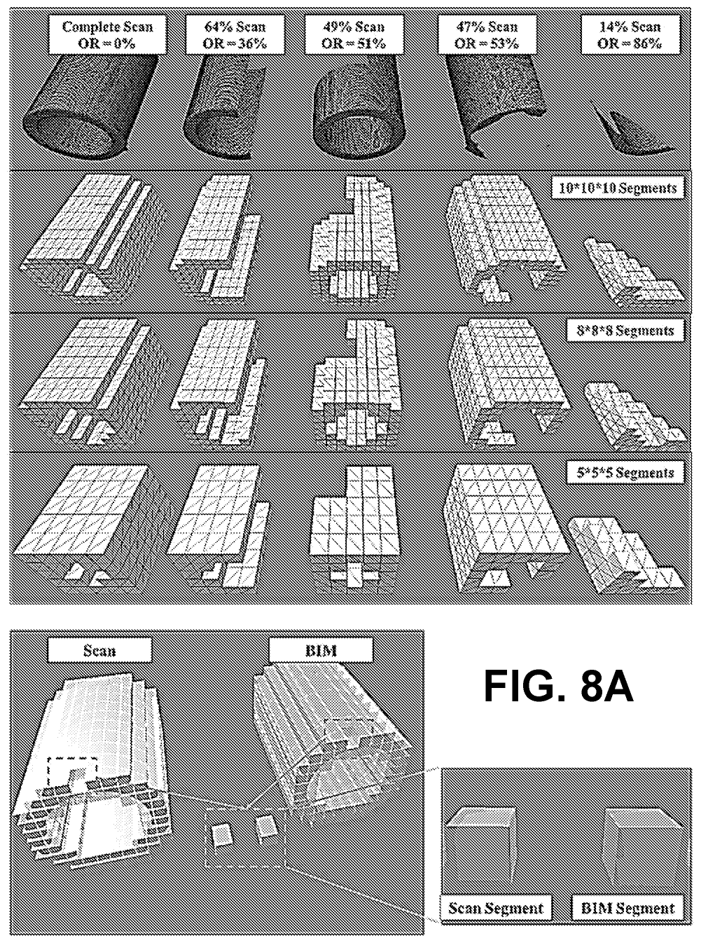

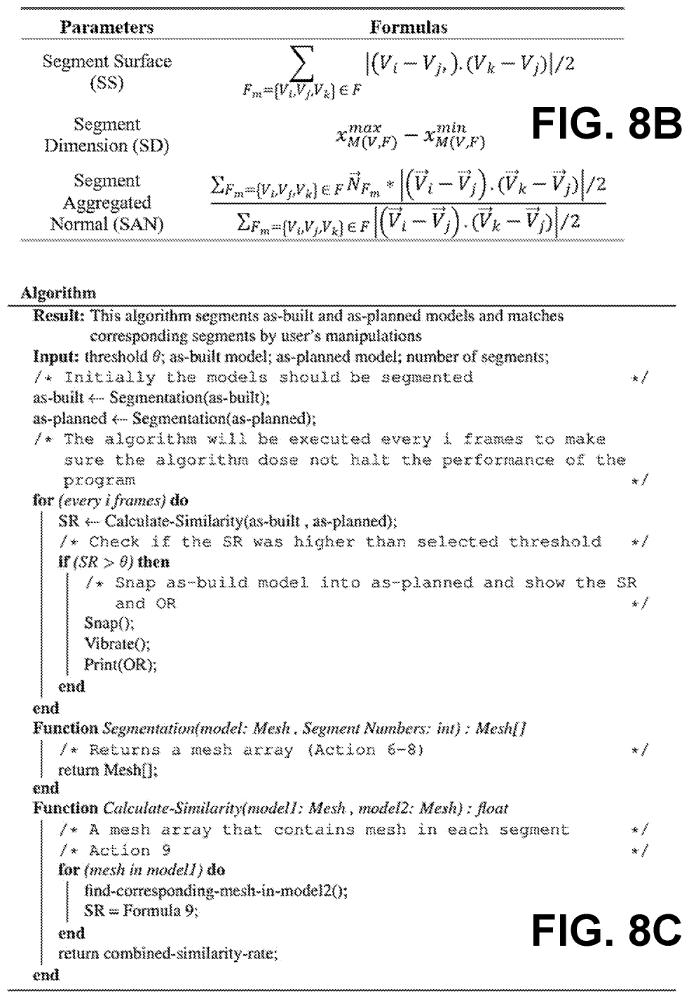

FIG. 8A illustrates an example of the segmentation process 703 for the BIM and scanned models. The similarity check function can operate based on the following mathematical definitions, operations, and steps that compare BIM and scan models segments. A mesh M is defined as a triangulated planar surface that comprises three vertices (Vᵢ, Vⱼ, Vₖ). Each vertex V is created from three values showing a 3D coordinate (i.e., x, y, z). Each face F can be created by connecting (Vᵢ, Vⱼ, Vₖ). The mesh can thus be defined as M (V, F). Consequently, the normal of a face in a mesh N F can be defined as follows:

$$\\ \begin{matrix}∀ {F}_{m} = \{ {V}_{i} , {V}_{j} , {V}_{k} \} ∈ M ( V , F ) : {\vec{N}}_{{F}_{m}} = \frac{( {\vec{V}}_{i} - {\vec{V}}_{j} ) \times ( {\vec{V}}_{k} - {\vec{V}}_{j} )}{\vert ( {\vec{V}}_{i} - {\vec{V}}_{j} ) \times ( {\vec{V}}_{k} - {\vec{V}}_{j} ) \vert} . & ( 1 )\end{matrix}$$

The highest point (top point) of a mesh or mesh segment M in each direction can defined as follows, where p is (x, y, z):

p^{max}=Max(v∈V in M(V,F). (2)

Consequently, the lowest point of a mesh or mesh segment M in each direction can be defined as follows:

p^{min}=Min(v∈V in M(V,F). (3)

The delta value (the dimension) of a mesh in each direction can be defined as follows:

Δ^{v}=p^{max}−p^{min}. (4)

The upper and lower boundary of each segment is needed to calculate and useful in the process of segmentation. A segment can be defined as follows:

seg(i,j,k):i,j,k∈{1, . . . ,SC}, (5)

where SC (segment count) is the number of segments in each direction.

Calculation of the boundaries of the segments can be useful as these values can be used to split the model (BIM or scan) into the segments. The lower boundary of a mesh segment M in each direction can be defined as follows:

$$\\ \begin{matrix}{Bound}_{low}^{p} ( seg ( i , j , k ) ) = {p}^{min} + {Δ}^{p} * \frac{i - 1}{SC} . & ( 6 )\end{matrix}$$

Similarly, the upper boundary of a mesh segment M in each direction of a segment can be defined as follows:

$$\\ \begin{matrix}{Bound}_{up}^{p} ( seg ( i , j , k ) ) = {p}^{min} + {Δ}^{p} * \frac{i}{SC} . & ( 7 )\end{matrix}$$

To compare the as-built and as-planned segments, the three parameters in each segment can be defined as summarized in the table of FIG. 8B. The first parameter is the surface area of the mesh inside the segment defined as segment surface (SS). The second parameter is the segment dimension (SD), which can be defined as the dimensions of the mesh inside the segment. Third, the segment aggregated normal (SAN) can be defined as a weighted normal vector of the mesh triangles, in which the weights are the area of each triangle.

The following formula (8) can be defined to calculate the similarity ratio (SR) between each segment pair. In this case, the values of each parameter for as-built and as-planned segments are compared and used to create the SR ratio.

$$\\ \begin{matrix}SR ( {seg}_{( i , j , k )}^{{M}_{Scan}} , {seg}_{( i , j , k )}^{{M}_{BIM}} ) = {\frac{SS ( {seg}_{( i , j , k )}^{{M}_{BIM}} )}{SS ( {seg}_{( i , j , k )}^{{M}_{Scan}} )}}^{\begin{matrix}sgn ( SS ( {seg}_{( i , j , k )}^{{M}_{Scan}} ) - SS ( {seg}_{( i , j , k )}^{{M}_{BIM}} ) ) \\ \end{matrix}} * {\prod }_{dir = \{ x , y , z \}} {\frac{{SD}_{dir} ( {seg}_{( i , j , k )}^{{M}_{BIM}} )}{{SD}_{dir} ( {seg}_{( i , j , k )}^{{M}_{Scan}} )}}^{\begin{matrix}sgn ( {SD}_{dir} ( {seg}_{( i , j , k )}^{{M}_{Scan}} ) - {SD}_{dir} ( {seg}_{( i , j , k )}^{{M}_{BIM}} ) ) \\ \end{matrix}} * {\prod }_{dir = \{ x , y , z \}} {\frac{{SAN}_{dir} ( {seg}_{( i , j , k )}^{{M}_{BIM}} )}{{SAN}_{dir} ( {seg}_{( i , j , k )}^{{M}_{Scan}} )}}^{\begin{matrix}sgn ( {SAN}_{dir} ( {seg}_{( i , j , k )}^{{M}_{Scan}} ) - {SAN}_{dir} ( {seg}_{( i , j , k )}^{{M}_{BIM}} ) ) \\ \end{matrix}} . & ( 8 )\end{matrix}$$

The following formula (9) further expands the SR formula (8) for all the segments and to aggregate the total SR from SR between each segment pair.

SR(M_{scan},M_{BIM})=Π_{i,j,k}SR(Seg_{(i,j,k)}^{Mscan},Seg_{(i,j,k)}^{MBIM} (9)

FIG. 8C illustrates an example of an algorithm to implement the similarity check function for segmentation and similarity determination.

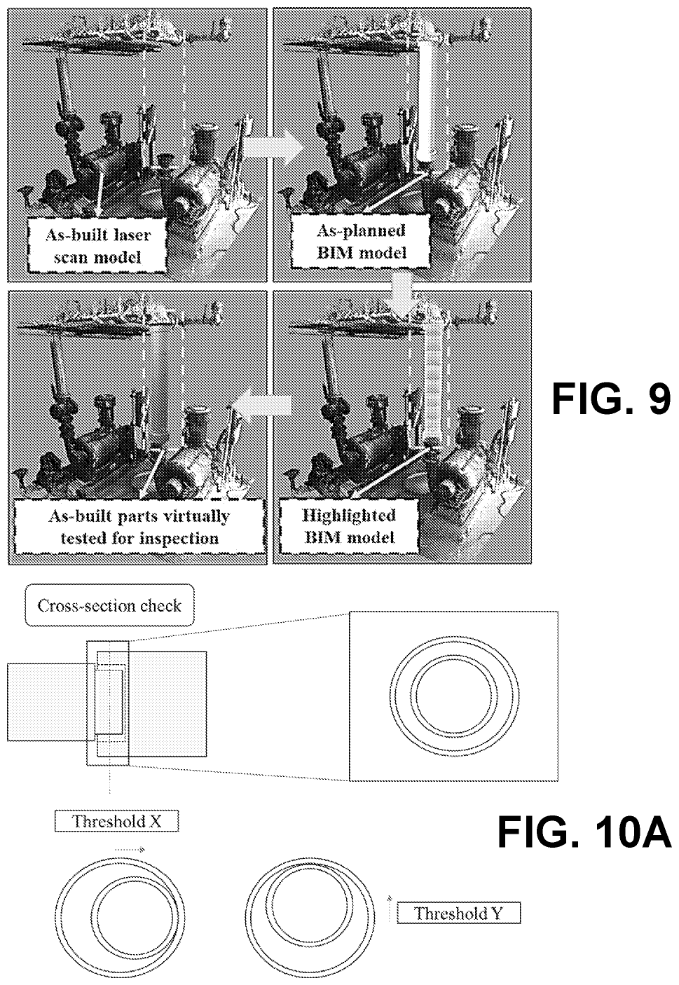

The simulation of manipulation in the VR space allows testing of the parts before actual shipment of the parts occurs. FIG. 9 shows an example of how this section fits in practice and illustrates the process of bringing elements virtually to the site (e.g., facility or construction site), and visually inspect and check for compatibility issues before shipping the prefabricated element. During construction, compatibility issues of prefabricated components can be avoided by this process before arrive at a job site, similarly, during operation and maintenance, compatibility issues can be avoided for any replacement parts/components (e.g., an old steam generator in a power plant) that will arrive at the facility with quality assurance. In this way, any discrepancies in the as-built component can be addressed at the manufacturing facilities which reduces costs and improves delivery.

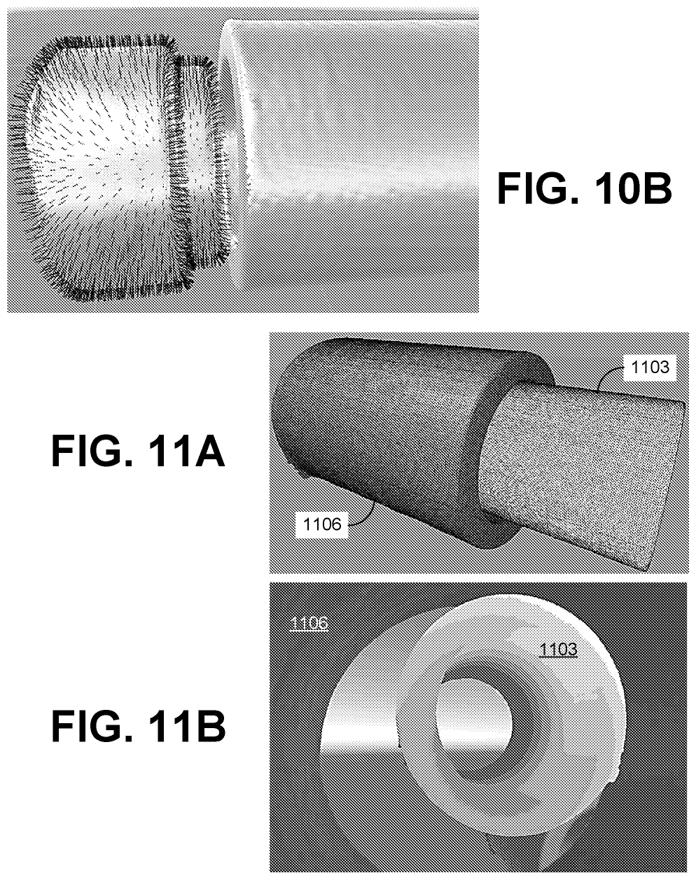

As-built to as-built compatibility in a coupling system. A compatibility algorithm can be used to check the compliance of as-built components in a coupling system. FIGS. 10A and 10B show a simple coupling system where two pipes are coupled together. FIG. 10A shows cross-sectional views of the components for comparison. The compatibility check algorithm can check the cross-section of both components and calculate the thresholds in each direction as illustrated in FIG. 10B. This threshold can be color-coded to visualize deviations of as-built components and indicate or mark them as incompatible.

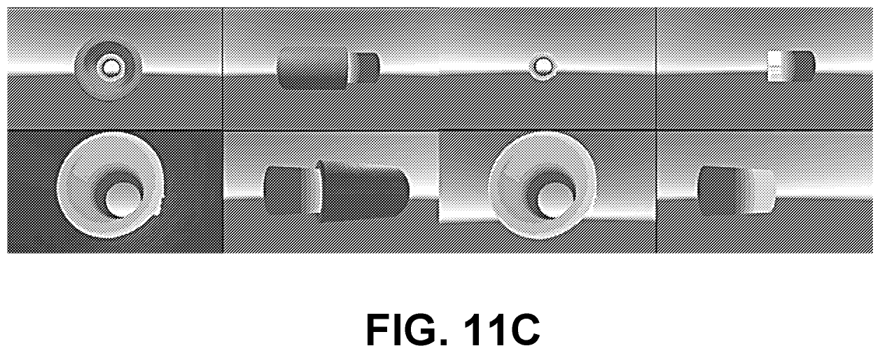

FIG. 11A illustrates an example of a coupling system having an inner pipe 1103 and an outer pipe 1106. To generate the as-built models of the components, both of the pipes 1103 and 1106 can be scanned separately using a laser scanner (e.g., Artec Eva). FIG. 11B shows the color-coded pipes in the coupling system. The whiter vertices show a closer distance to the outer pipe 1106, where darker vertices show a larger distance from the outer pipe 1106. The compatibility algorithm can calculate the distance from each vertex of the small inner pipe 1103 to the larger outer pipe 1106. To improve the user's visualization, a user interface can be designed to display the models so that the user can see the coupling system from different viewpoints and turn each of the components off for a better view of each component separately. FIG. 11C shows the preliminary results of the compatibility system for the coupling system from different viewpoints, where the user can clearly see the parts that need modification prior to installation.

Framework capabilities. The capabilities of the monitoring framework for modular construction will now be discussed. This disclosure has presented components of the CPMS, including as-built modeling at the main project site and off-site facilities, data captures through advances in robotics and computer vision, and virtual environment that visualizes as-built models and as-planned BIM. The presented CPMS can allow visualization of actual construction progress compared against plans (4D BIM). As 4D BIM has an embedded construction schedule, reasoning about the dependencies of construction activities along with the compared progress can allow traveling back in time to identify root-causes and forward in time to identify potential issues. CPMS can serve as a monitoring and digital data management solution that can serve all stakeholders of a construction project, including owners, construction managers, general contractors, subcontractors, and vendors. The framework capabilities can include, e.g.:
Seamlessly render a plurality of point clouds along with the BIM model.
Render the point clouds in real-time (the frame rate can be higher than 60 FPS) and visualize frame per second and number of rendered point in real-time.
Render point clouds from laser scanning and/or photogrammetry approaches.
Capable of switching between point clouds seamlessly based on the time that the point cloud is acquired.
Color code the BIM elements based on the production or construction schedule to indicate if the element is ahead or behind schedule.
Register the point clouds and BIM with high precision, which can be up to 1 to 6 inches,
Visualize images that have been used to perform 3D reconstruction in their corresponding position related to BIM and point clouds.
Perform compatibility checking between as-built and as-planned (point cloud and BIM) models through a compatibility checking mode.
Inspect the couplings and joint through comparison of as-built and as-built models in a joint or other interface.
The framework (including both Unity version and Three.JS light version for web) is capable of working on a variety of systems including, but not limited to, Windows, Mac, Web, and/or Linux systems.

The compatibility checking and management methodology brings project site and off-site facilities into a virtual environment that enables virtual assembly of modular components that are fabricated off-site such as those utilized in nuclear or other industries, ensuring the quality and compatibility of different components before shipment. In addition, this technology enables a holistic approach to digital record generation and management in the supply chain loop. Every process of fabrication, assembly (both on-site and virtual), and inspection can be documented by as-built 3D point clouds and as-planned construction and fabrication models. The disclosed technology can significantly reduce the associated uncertainties and prevent unforeseen delays and cost overruns that are caused by quality and compatibility issues, addressing risks associated with uncertain construction cost and schedule, especially for facilities with complex design.

Computing or processing device(s) can be utilized to implement the compatibility checking and management system. In some embodiments, among others, the computing or processing device may represent a mobile device (e.g. a smartphone, tablet, computer, etc.). Each computing or processing device can include at least one processor circuit, for example, having a processor and memory coupled to a local interface. To this end, each computing or processing device may comprise, for example, at least one server computer or like device. The local interface may comprise, for example, a data bus with an accompanying address/control bus or other bus structure as can be appreciated. In some embodiments, the computing device can include one or more network interface(s), which may comprise, for example, a wireless transmitter, a wireless transceiver, and a wireless receiver.

Stored in the memory are both data and several components that are executable by the processor. In particular, stored in the memory and executable by the processor are one or more compatibility checking and management application(s). It is understood that there may be other applications that are stored in the memory and executable by the processor as can be appreciated. In this respect, the term “executable” means a program file that is in a form that can ultimately be run by the processor. Where any component discussed herein is implemented in the form of software, any one of a number of programming languages may be employed. An executable program may be stored in any portion or component of the memory including, for example, random access memory (RAM), read-only memory (ROM), hard drive, solid-state drive, USB flash drive, memory card, optical disc such as compact disc (CD) or digital versatile disc (DVD), floppy disk, magnetic tape, or other memory components. If embodied in dedicated hardware, each can be implemented as a circuit or state machine that employs any one of or a combination of a number of technologies. These technologies may include, but are not limited to, discrete logic circuits having logic gates for implementing various logic functions upon an application of one or more data signals, application specific integrated circuits (ASICs) having appropriate logic gates, field-programmable gate arrays (FPGAs), or other components, etc. Such technologies are generally well known by those skilled in the art and, consequently, are not described in detail herein.

Also, any logic or application described herein, including the compatibility checking and management application(s), that comprises software or code can be embodied in any non-transitory computer-readable medium for use by or in connection with an instruction execution system such as, for example, a processor in a computer system or other system. In this sense, the logic may comprise, for example, statements including instructions and declarations that can be fetched from the computer-readable medium and executed by the instruction execution system. In the context of the present disclosure, a “computer-readable medium” can be any medium that can contain, store, or maintain the logic or application described herein for use by or in connection with the instruction execution system.

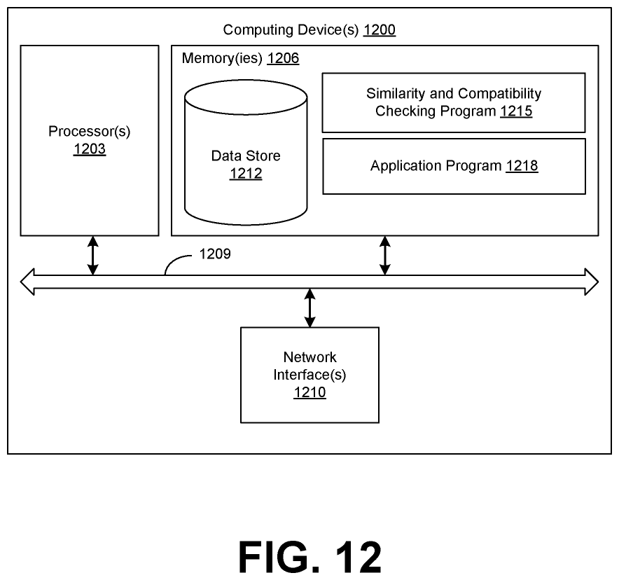

With reference to FIG. 12, shown is a schematic block diagram of a computing (or processing) device 1200 that can be utilized for similarity and compatibility checking and management for modular construction using the described techniques. In some embodiments, among others, the computing device 1200 may represent a mobile device (e.g. a smartphone, tablet, computer, etc.) or other processing device. Each computing device 1200 includes processing circuitry comprising at least one processor circuit, for example, having a processor 1203 and a memory 1206, both of which are coupled to a local interface 1209. To this end, each computing device 1200 may comprise, for example, at least one server computer or like device. The local interface 1209 may comprise, for example, a data bus with an accompanying address/control bus or other bus structure as can be appreciated.

In some embodiments, the computing device 1200 can include one or more network interfaces 1210. The network interface 1210 may comprise, for example, a wireless transmitter, a wireless transceiver, and a wireless receiver. As discussed above, the network interface 1210 can communicate to a remote computing device using a Bluetooth protocol. As one skilled in the art can appreciate, other wireless protocols may be used in the various embodiments of the present disclosure.

Stored in the memory 1206 are both data and several components that are executable by the processor 1203. In particular, stored in the memory 1206 and executable by the processor 1203 are similarity and compatibility checking program 1215, application program 1218, and potentially other applications. For example, the similarity and compatibility checking program 1215 can be implemented within a construction performance modeling and simulation (CPMS) framework. Also stored in the memory 1206 may be a data store 1212 and other data. In addition, an operating system may be stored in the memory 1206 and executable by the processor 1203.

It is understood that there may be other applications that are stored in the memory 1206 and are executable by the processor 1203 as can be appreciated. Where any component discussed herein is implemented in the form of software, any one of a number of programming languages may be employed such as, for example, C, C++, C #, Objective C, Java®, JavaScript®, Perl, PHP, Visual Basic®, Python®, Ruby, Flash®, or other programming languages.

A number of software components are stored in the memory 1206 and are executable by the processor 1203. In this respect, the term “executable” means a program file that is in a form that can ultimately be run by the processor 1203. Examples of executable programs may be, for example, a compiled program that can be translated into machine code in a format that can be loaded into a random access portion of the memory 1206 and run by the processor 1203, source code that may be expressed in proper format such as object code that is capable of being loaded into a random access portion of the memory 1206 and executed by the processor 1203, or source code that may be interpreted by another executable program to generate instructions in a random access portion of the memory 1206 to be executed by the processor 1203, etc. An executable program may be stored in any portion or component of the memory 1206 including, for example, random access memory (RAM), read-only memory (ROM), hard drive, solid-state drive, USB flash drive, memory card, optical disc such as compact disc (CD) or digital versatile disc (DVD), floppy disk, magnetic tape, or other memory components.

The memory 1206 is defined herein as including both volatile and nonvolatile memory and data storage components. Volatile components are those that do not retain data values upon loss of power. Nonvolatile components are those that retain data upon a loss of power. Thus, the memory 1206 may comprise, for example, random access memory (RAM), read-only memory (ROM), hard disk drives, solid-state drives, USB flash drives, memory cards accessed via a memory card reader, floppy disks accessed via an associated floppy disk drive, optical discs accessed via an optical disc drive, magnetic tapes accessed via an appropriate tape drive, and/or other memory components, or a combination of any two or more of these memory components. In addition, the RAM may comprise, for example, static random access memory (SRAM), dynamic random access memory (DRAM), or magnetic random access memory (M RAM) and other such devices. The ROM may comprise, for example, a programmable read-only memory (PROM), an erasable programmable read-only memory (EPROM), an electrically erasable programmable read-only memory (EEPROM), or other like memory device.

Also, the processor 1203 may represent multiple processors 1203 and/or multiple processor cores and the memory 1206 may represent multiple memories 1206 that operate in parallel processing circuits, respectively. In such a case, the local interface 1209 may be an appropriate network that facilitates communication between any two of the multiple processors 1203, between any processor 1203 and any of the memories 1206, or between any two of the memories 1206, etc. The local interface 1209 may comprise additional systems designed to coordinate this communication, including, for example, performing load balancing. The processor 1203 may be of electrical or of some other available construction.

Although the similarity and compatibility checking program 1215 and the application program 1218, and other various systems described herein may be embodied in software or code executed by general purpose hardware as discussed above, as an alternative the same may also be embodied in dedicated hardware or a combination of software/general purpose hardware and dedicated hardware. If embodied in dedicated hardware, each can be implemented as a circuit or state machine that employs any one of or a combination of a number of technologies. These technologies may include, but are not limited to, discrete logic circuits having logic gates for implementing various logic functions upon an application of one or more data signals, application specific integrated circuits (ASICs) having appropriate logic gates, field-programmable gate arrays (FPGAs), or other components, etc. Such technologies are generally well known by those skilled in the art and, consequently, are not described in detail herein.

Also, any logic or application described herein, including the similarity and compatibility checking program 1215 and the application program 1218, that comprises software or code can be embodied in any non-transitory computer-readable medium for use by or in connection with an instruction execution system such as, for example, a processor 1203 in a computer system or other system. In this sense, the logic may comprise, for example, statements including instructions and declarations that can be fetched from the computer-readable medium and executed by the instruction execution system. In the context of the present disclosure, a “computer-readable medium” can be any medium that can contain, store, or maintain the logic or application described herein for use by or in connection with the instruction execution system.

The computer-readable medium can comprise any one of many physical media such as, for example, magnetic, optical, or semiconductor media. More specific examples of a suitable computer-readable medium would include, but are not limited to, magnetic tapes, magnetic floppy diskettes, magnetic hard drives, memory cards, solid-state drives, USB flash drives, or optical discs. Also, the computer-readable medium may be a random access memory (RAM) including, for example, static random access memory (SRAM) and dynamic random access memory (DRAM), or magnetic random access memory (MRAM). In addition, the computer-readable medium may be a read-only memory (ROM), a programmable read-only memory (PROM), an erasable programmable read-only memory (EPROM), an electrically erasable programmable read-only memory (EEPROM), or other type of memory device.

Further, any logic or application described herein, including the similarity and compatibility checking program 1215 and the application program 1218, may be implemented and structured in a variety of ways. For example, one or more applications described may be implemented as modules or components of a single application. For example, separate applications can be executed for the similarity and compatibility checking and management workflows as illustrated in FIGS. 3 and 7. Further, one or more applications described herein may be executed in shared or separate computing devices or a combination thereof. For example, a plurality of the applications described herein may execute in the same computing device 1200, or in multiple computing devices in the same computing environment. Additionally, it is understood that terms such as “application,” “service,” “system,” “engine,” “module,” and so on may be interchangeable and are not intended to be limiting.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

The term “substantially” is meant to permit deviations from the descriptive term that don't negatively impact the intended purpose. Descriptive terms are implicitly understood to be modified by the word substantially, even if the term is not explicitly modified by the word substantially.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’” includes “about ‘x’ to about y”.

Therefore, at least the following is claimed:

1. A method for compatibility checking of modular construction, comprising:
segmenting boundaries of as-built and as-planned models of a construction element;
determining features of each boundary segment of the as-built and as-planned models;
determining similarity ratios for matching pairs of boundary segments of the as-built and as-planned models;
comparing a total similarity ratio based upon the similarity ratios for matching pairs of boundary segments with a specified threshold; and
snapping the as-built model in position in a point cloud in response to the comparison.

2. The method of claim 1, wherein the determined features of each boundary segment of the as-built and as-planned models comprise segment surface, segment dimension, and segment aggregated normal.

3. The method of claim 2, wherein the similarity ratios for matching pairs of boundary segments are based upon the segment surface, segment dimension, and segment aggregated normal of the matching pair of boundary segments of the as-built and as-planned models.

4. The method of claim 1, wherein determining features of each boundary segment comprises determining highest and lowest points in a plurality of defined directions for each boundary segment.

5. The method of claim 1, wherein the as-built model is snapped in position when the total similarity ratio is less than or equal to the specified threshold.

6. The method of claim 5, wherein registration of the as-built model in the point cloud is adjusted in response to the total similarity ratio exceeding the specified threshold.

7. The method of claim 1, wherein the as-built and as-planned models are identified by a common global unique identifier (GUI D).

8. The method of claim 1, wherein the construction element is configured to couple to a second construction element along a coupling interface.

9. The method of claim 8, further comprising comparing the as-built model of the construction element to an as-built model of the second construction element along the coupling interface.

10. The method of claim 9, wherein the comparison comprises comparing features of boundary segments along the coupling interface of the as-built model of the construction element to features of corresponding boundary segments along the coupling interface of the as-built model of the second construction element.

11. The method of claim 10, wherein the features of each boundary segment comprises highest and lowest points in a plurality of defined directions for each boundary segment.

12. The method of claim 9, wherein the as-built models of the construction elements are displayed in a user interface in a coupled orientation.

13. The method of claim 1, wherein the compatibility checking method is implemented within a construction performance modeling and simulation (CPMS) framework.

14. A system, comprising:
processing circuitry comprising a processor and memory; and
a similarity and compatibility checking program executable by the processing circuitry, where execution of the similarity and compatibility checking program causes the processing circuitry to:
segment boundaries of as-built and as-planned models of a construction element;
determine features of each boundary segment of the as-built and as-planned models;
determine similarity ratios for matching pairs of boundary segments of the as-built and as-planned models;
compare a total similarity ratio based upon the similarity ratios for matching pairs of boundary segments with a specified threshold; and
snap the as-built model in position in a point cloud in response to the comparison.

15. The system of claim 14, wherein the determined features of each boundary segment of the as-built and as-planned models comprise segment surface, segment dimension, and segment aggregated normal.

16. The system of claim 15, wherein the similarity ratios for matching pairs of boundary segments are based upon the segment surface, segment dimension, and segment aggregated normal of the matching pair of boundary segments of the as-built and as-planned models.

17. The system of claim 14, wherein the as-built model is snapped in position when the total similarity ratio is less than or equal to the specified threshold.

18. The system of claim 17, wherein registration of the as-built model in the point cloud is adjusted in response to the total similarity ratio exceeding the specified threshold.

19. The system of claim 14, wherein execution of the similarity and compatibility checking program causes the processing circuitry to compare the as-built model of the construction element to an as-built model of a second construction element along a coupling interface.

20. The system of claim 19, wherein the comparison comprises comparing features of boundary segments along the coupling interface of the as-built model of the construction element to features of corresponding boundary segments along the coupling interface of the as-built model of the second construction element.
